(19) United States
(12) Patent Application Publication
(10) Pub. No.: US 2026/0064169 A1
(43) Pub. Date: Mar. 5, 2026

(54) RETENTION MECHANISIM FOR MEMORY MODULES

(71) Applicant: Advanced Micro Devices, Inc., Santa Clara, CA (US)

(72) Inventors: Christopher Edward COX, Folsom, CA (US); Aaron John NYGREN, Boise, ID (US)

(21) Appl. No.: 19/023,128

(22) Filed: Jan. 15, 2025

Related U.S. Application Data
(60) Provisional application No. 63/688,774, filed on Aug. 29, 2024.
(60) Provisional application No. 63/688,852, filed on Aug. 29, 2024.

(51) Int. Cl. G06F 1/18; H05K 7/20

(52) U.S. Cl. CPC G06F 1/187; H05K 7/2039

(57) ABSTRACT

A computer system includes device circuitry includes connectors, memory modules, and a retention mechanism. The memory modules are disposed within the connectors. The retention mechanism is connected to the memory modules. The retention mechanism includes slots. Each of the slots receives one of the memory modules.

### CROSS REFERENCE TO RELATED APPLICATIONS

This application claims the benefit of United States provisional patent application Ser. No. 63/688,774, filed Aug. 29, 2024, and United States provisional patent application Ser. No. 63/688,852, filed Aug. 29, 2024, which is hereby incorporated herein by reference.

### TECHNICAL FIELD

Examples of the present disclosure generally relate to a retention mechanism for mitigating the effects of stress and movement of memory modules in a computer system.

### BACKGROUND

A computer system includes memory modules. The memory modules may be random access memory (RAM) memory modules. The memory modules may be dual in-line memory modules. A memory module may include a printed circuit board having memory devices disposed one or more surfaces of the printed circuit board. The memory modules are installed within sockets in a printed circuit board (e.g., motherboard) of the computer system. The sockets provide physical and electrical connections for the memory modules. The memory modules communicate with other elements of the computer system via connections on the printed circuit board and the sockets.

### SUMMARY

In one example, a computer system includes connectors, memory modules, and a retention mechanism. The memory modules are disposed within the connectors. The retention mechanism is connected to the memory modules. The retention mechanism includes slots. Each of the slots receives one of the memory modules.

In one example, a retention mechanism includes slots. Each slot of the slots receives a memory module of memory modules of a computer system. The memory modules are disposed within connectors of the computer system.

In one example, a method includes providing a computer system including connectors. Further, the method includes providing memory modules. The memory modules are disposed within the connectors. The method further includes providing a retention mechanism. The retention mechanism is connected to the memory modules. The retention mechanism includes slots. Each of the slots receives one of the memory modules.

These and other aspects may be understood with reference to the following detailed description

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a block diagram of a computer system.

FIG. 2A illustrates a block diagram of a retention mechanism and memory modules.

FIG. 2B illustrates a block diagram of retention mechanisms and memory modules.

FIG. 3A illustrates a block diagram of memory modules, retention mechanisms and retention elements.

FIG. 3B illustrates a block diagram of memory modules, retention mechanisms and retention elements.

FIG. 3C illustrates a block diagram of memory modules, retention mechanisms and retention elements that are not engaged with the memory modules.

FIG. 3D illustrates a block diagram of memory modules, retention mechanisms and retention elements that are engaged with the memory modules.

FIG. 3E illustrates a block diagram of memory modules having heatsinks, retention mechanisms and retention elements.

FIG. 3F illustrates a block diagram of memory modules, retention mechanisms and retention elements.

FIG. 4 illustrates a block diagram of a computer system having a chassis and a retention mechanism for the memory modules.

FIG. 5 illustrates a flowchart for providing a computer system having memory modules and a retention mechanism.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

In a computer system, the physical size of the memory modules is one limitation to the amount memory that can be placed on the memory modules. Tall form factor memory modules have an increased height to allow for additional rows of memory devices to be included within the memory modules, increasing the amount of memory of the memory modules. A memory module may be a dual in-line memory module (DIMM), where memory devices are installed to two opposing surfaces of the memory module. In other examples, other types of memory modules may be used. Tall format memory modules shift the center of gravity, and the weight of the memory modules. Accordingly, any movement (e.g., swaying) of a tall format memory module may cause flex to occur at the connector where the tall format memory module is connected to a printed circuit board of the computer system, placing stress on the connector, and the connector may fail.

Regular movement of the corresponding computer system, or platform, may cause vibrations within the tall format memory modules, damaging the memory modules and/or the connectors (or sockets) connected to the memory modules. For example, moving the computer system could cause the tall format to tear out of (i.e., separate from) the connector, and causing a short, electrical, or mechanical failure.

In the following, an improved retention mechanism is proposed for memory modules. While the retention mechanism may be described with regard to a tall format memory module, the retention mechanism may be used with any size memory module. Further, the retention mechanism may be used with any type of memory module (e.g., a DIMM or other type of memory module). As is described in detail in the following, the retention mechanism is connected to the top edge of the memory modules and holds the corresponding memory modules in place.

The retention mechanism is a connector bar that can be included as part of a chassis of the computer system or external to the computer system. In one example, the retention mechanism is attached to the chassis or to standoffs inside of the chassis. The retention mechanism includes slots for receiving the memory modules. The retention mechanism and the slip in style slots are shaped with a slope such that the memory modules are guided into the slots during installation and upon engaging with the retention mechanism. Moreover, the retention mechanism and the slots may be configured in an aerodynamic manner so as to promote good air flow across the memory modules. So while the drawings providing herein shows exaggerated angles, the sidewalls of the slots may be close to vertical or even vertical on one or both sides.

Further, the retention mechanism may include retention pins that align with the memory modules. The retention pins may be part of the retention mechanism, or be disposed through thought holes formed in the chassis of the housing of the computing system in which the memory modules are mounted.

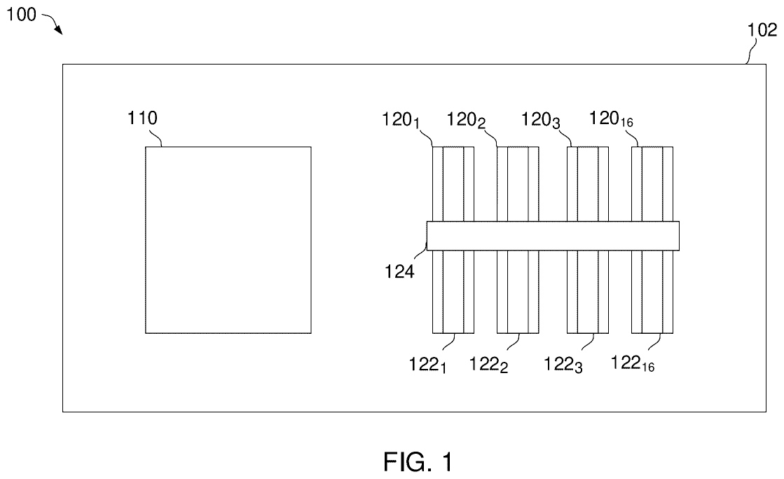

FIG. 1 illustrates a block diagram of a computer system 100. The computer system 100 includes a processing device 110, connectors 120, memory modules 122, and one or more retention mechanisms 124. The computer system 100 may be personal computer system. In other examples, the computer system 100 is part of a distributed computer system. In such an example, the computer system 100 may be referred to as a server. Further, in a distributed computer system, the computer system 100 is connected (e.g., a wireless and/or wired connection) to other computer systems to perform various operations.

The processing device 110 is a central processing unit (CPU) or graphics processing unit (GPU), among others. In one example, the computer system 100 includes one or more processing devices. In such an example, the processing devices 110 may be the same or different types.

The processing device 110 is connected to the memory modules 122 via the connectors 120. For examples, traces are used to connect the processing device 110 with the connectors 120. The memory modules 122 are mounted within the connectors 120. In one example, the connectors 120 are physically and electrically connected to the memory modules 122. In one example, the connectors 120 include a clamping mechanism that holds the memory modules 122. The connectors 120 may be referred to as a socket.

In one or more examples, the processing device 110 and the connectors 120 are disposed on a printed circuit board (PCB) 102 of the computer system 100.

Each of the memory modules 122 includes one or more memory devices. A memory module 122 may be a dual in-line memory module (DIMM). In other examples, other types of memory modules 122 may be used. The number of memory devices corresponds to the memory capacity of a memory module 122. In one example, the number of memory devices that can be included within a memory module 122 is limited to the size of the memory module 122. Accordingly, one or more dimensions of a memory module 122 may be increased to allow for a larger number of memory devices to be mounted to the memory module 122. In one example, the height of the memory module 122 is increased. Such a memory module is referred to as a tall format memory module.

The memory devices are double data rate (DDR) memory devices. In other examples, other types of memory devices may be used. The memory devices may be disposed in rows and columns on one or two sides of a memory module 122. In one example, increasing a size of a memory module 122 increases the number of rows of memory devices that can be included on the memory module 122, increasing the memory capacity of the memory module 122 and corresponding computer system (e.g., the computer system 100). In one example, a tall format memory module includes more than 2 rows of memory devices.

The retention mechanism 124 engages each of the memory modules 122. In one example, the retention mechanism 124 is connected to a side of the memory modules 122 (e.g. the top side) opposite the side of the memory modules 122 that is connected to the connectors 120. In other examples, the retention mechanism 124 may be connected to another side of the memory modules 122.

In one example, the computer system 100 includes a chassis. The chassis may be part of the housing of the computer system 100. The retention mechanism 124 may be at least partially included within the chassis or connected to the chassis. In one example, the retention mechanism 124 is connected to the chassis via standoff. In other examples, the retention mechanism 124 is not included, and is external, to the chassis and/or housing of the computer system 100. In one example, the retention mechanism 124 is connected to the housing of the computer system 100. The retention mechanism 124 can be slid or actuated to engage with the top edge of the memory modules 122 after the memory modules 122 have been installed (mounted) within the connectors 120, or even used to depress the memory modules 122 into engagement with the connectors 120. The retention mechanism 124 functions as a connector bar that adds stability to the memory modules 122 once connected to the memory modules 122.

In tall format memory modules (and other types of memory modules), there are mechanical problems that may occur when the corresponding computer system 100 is moved, during installation or service of the computer system 100, and/or during operation of the computer system 100, among other times. A memory module 122 (and especially tall format memory modules) may have a shifted center of gravity due to the size and/or weight of the memory module 122. Accordingly, flexing may occur at the connector 120, where a memory module 122 is connected to the connector 120. The flexing may be due to swaying of the memory module 122 and/or vibrations experienced by the memory module 122. The flexing places stress on the connector 120. The stress may cause the connector 120 to mechanically and/or electrically fail, causing operation of the corresponding memory module 122 to fail.

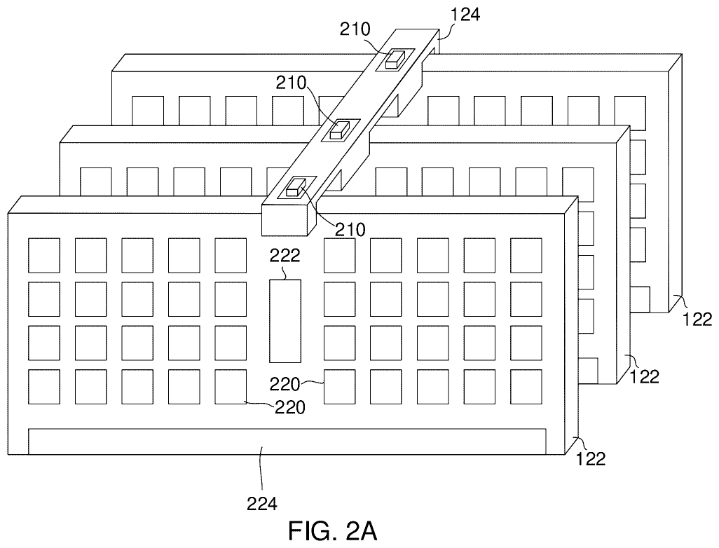

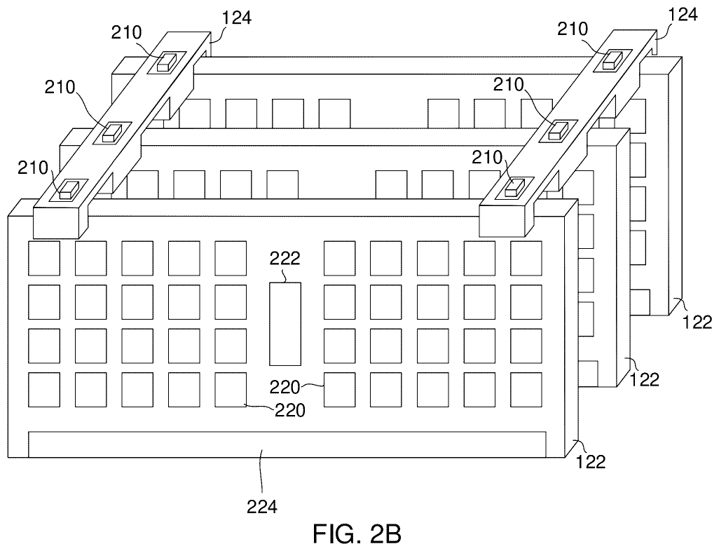

FIG. 2A illustrates the retention mechanism 124 and the memory modules 122. Although only one retention mechanism 124 is shown in FIG. 2A, one or more additional retention mechanisms 124 may be utilized arranged across the top edge of the memory modules 122 parallel with the retention mechanism 124 illustrated in FIG. 2. The retention mechanism 124 may be a plastic bar. In other examples, the retention mechanism 124 is formed from other materials. For example, the retention mechanism 124 may be formed from aluminum, copper, or other types of metals including alloys. In one or more examples, the retention mechanism 124 is formed from acrylonitrile butadiene styrene or thermoplastic polyurethane, among other type of plastics. In other examples, the retention mechanism 124 is formed from two or more different types of materials. In one or more examples, the retention mechanism 124 is 3D printed, injected molded, extruded, forged, stamped, pressed and/or casted, among others. The retention mechanism 124 includes one or more slots (notches or brackets) that are configured to receive a memory module 122.

The memory modules 122 include memory devices 220, control circuitry 222, and connectors 224. The connectors 224 are configured to fit within a socket (e.g., socket of a printed circuit board). The memory modules 122 include four rows of memory devices 220, however, in other examples, the memory modules 122 may include more than or less than four rows. The memory devices 220 may be disposed on both sides of the memory modules 122.

While the example of FIG. 2A illustrates a single retention mechanism 124, in the example of FIG. 2B two retention mechanisms 124 are illustrated. In an example that includes at least two retention mechanisms 124, a retention mechanism 124 may be attached along the top side 201 and proximate each of the edges 202 and 203 of the memory modules 122. In other examples, the retention mechanisms 124 may be attached at other positions along the top side 201 and/or along an edge 202 and/or 203 of the memory modules 122. In one or more examples, more than two retention mechanisms 124 may be used. For example, a retention mechanism 124 may be attached proximate the center of the memory modules 122 and proximate one or more of the edges of the memory modules 122. In one example, at least one retention mechanism 124 is disposed along a side edge of the memory modules 122.

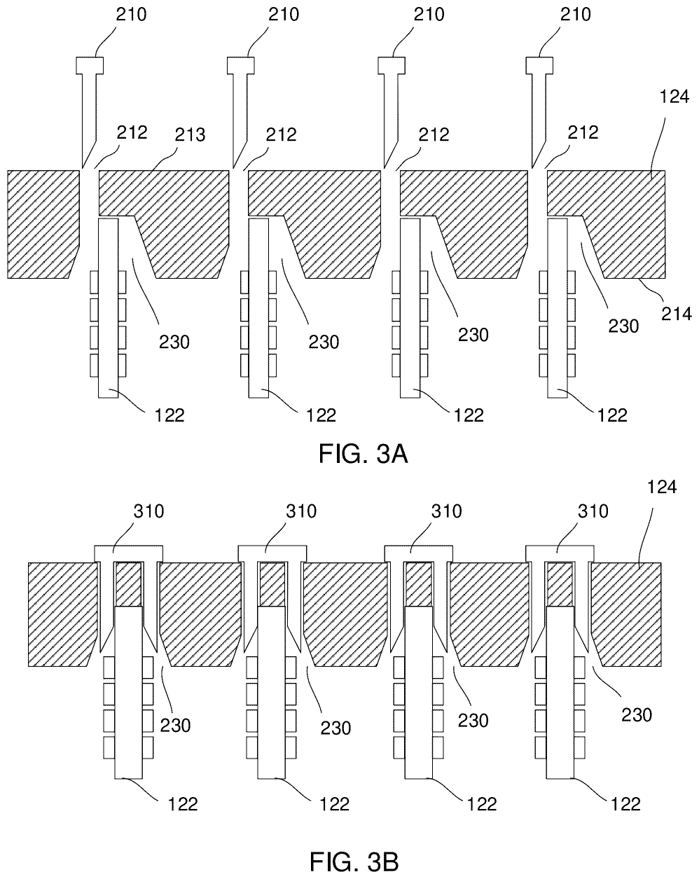

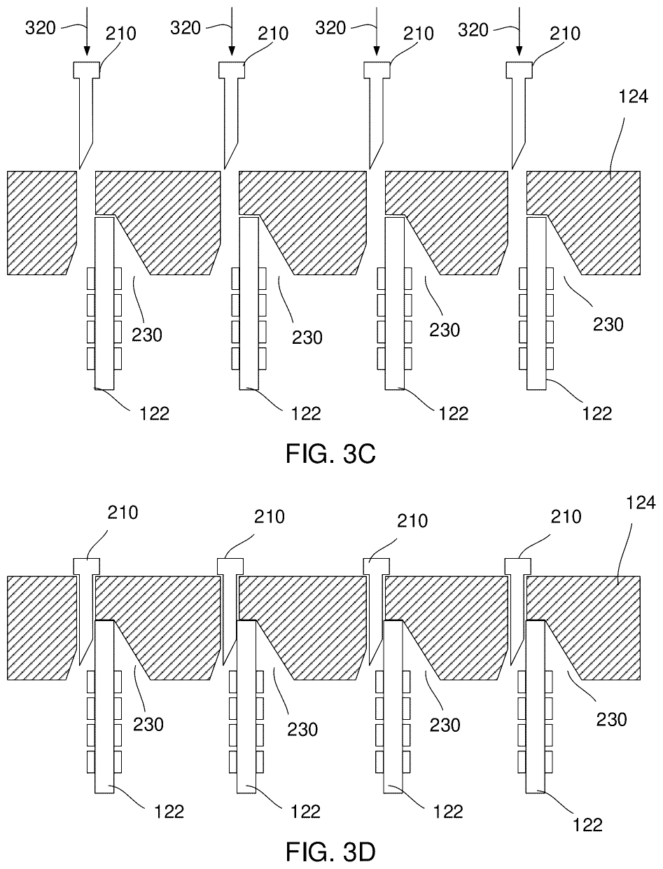

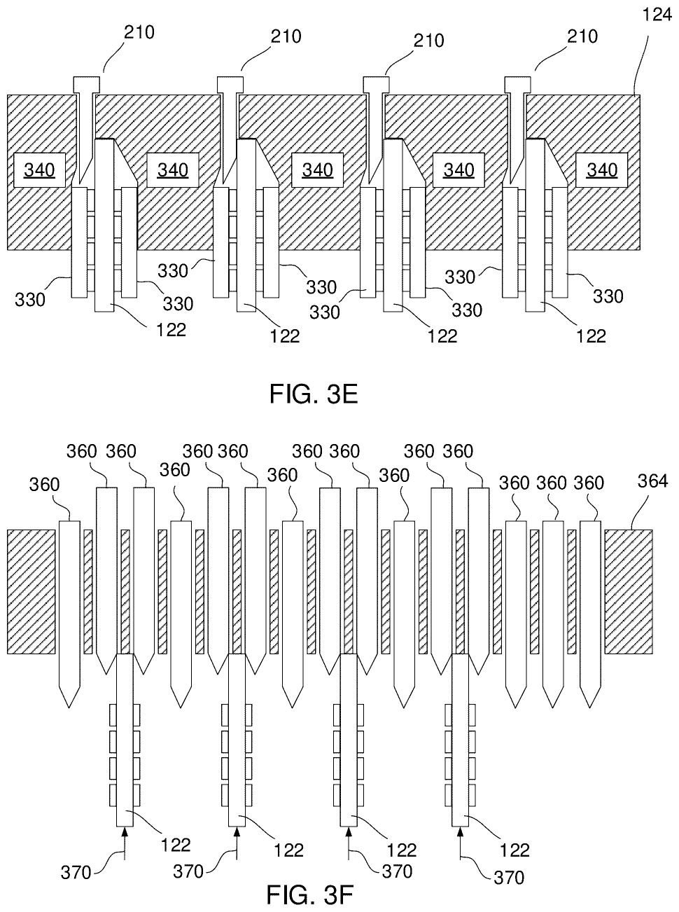

The retention mechanism 124 includes retention elements (retention pins or push pins) 210. The retention elements 210 may alternatively be disposed through holes in the housing of the computing system to engage the memory module 122 disposed in the slots 230 of the retention mechanism 124. Depressing the retention elements 210 extends retention elements 210 along the surface of the memory module 122, and aligns and secures the memory module 122 with the corresponding slot 230 and the retention mechanism 124. In one example, as is illustrated in FIG. 3A, the retention elements 210 are depressed into and through the body 214 of the retention mechanism. The retention elements 210 are generally long and strong enough to hold the memory module 122 in the slots 230. The retention elements 210 may each have the same length, two or more of the retention elements 210 may differ in length. Further, the thickness of the retention elements 210 corresponds to the width of the corresponding hole 212 in the body 214 of the retention mechanism 124. In one example, the thickness of the retention elements 210 is consistent along the length of the retention element 210. In another example, the thickness varies along the length of the retention element 210.

In one example, the retention elements 210 have a top portion 211 that contacts the surface 213 of the body 214 of the retention mechanism 124 when the retentions elements 210 are depressed.

At least a portion of the body 215 of the retention elements 210 is located is located within the hole 212 when the retention elements 210 are depressed. A width of the top portion 211 is greater than the thickness of the body 215.

The retention elements 210 are inserted through the holes (apertures) 212 formed within the body of the retention mechanism 124. In one example, the holes 212 are formed between a first surface 213 and a second surface 232 of the body of the retention mechanism 124. In one example, the slots 230 are formed in the surface 232 of the body 214. When engaged, the retention elements 210 may contact the surface 213.

The retention elements 210 may be round or non-round in cross section, such as a square or triangular cross section. The retention elements 210 may alternatively be configured as a screw or spiral such that twisting the push pin would tighten the memory module 122 securely in the slots 230. In one example, the retention element 210 is shaped to align the memory module 122 within a corresponding slot 230. Additionally, or alternatively, the retention element 210 is shaped to securely hold the memory module 122 within a corresponding slot 230.

As is illustrated in FIG. 3A, the retention mechanism 124 includes slots 230 for receiving the memory module 122. The slots 230 may be shaped (e.g., include one or more angled regions) to allow for improved alignment with the memory modules. The slots 230 may also be rectangular, or have another geometry that facilitate mating with and engaging the top edge of the memory modules 122.

The slots 230 are formed within the body 214 of the retention mechanism 124. The slots 230 are shaped to guide the memory modules 122 into the slots 230. Additionally or alternatively, the slots 230 are shaped to aid in securely holding the memory modules 122 within the slots. The slots 230 have at least one angled side (e.g., side 231). In other examples, the slots 230 may have a rectangular shape, or another shape. During installation, the memory modules 122 slide into the slots 230, which are shaped and/or include an alignment element (e.g., angled side 231) such that the memory modules 122 are able to mate (e.g., slide) into the correct slot 230. In one example during installation, a memory module 122 contacts the side 231, guiding the memory module 122 into the slot 230. Further, the retention element 210 is depressed to securely hold the memory module 122 within the slot 230.

In one example, elastomeric clips are used to mate the retention mechanism 124 with the memory modules 122. The elastomeric clips may be used in addition to or as an alternate to the retention elements 210.

The spacing between the slots 230 of the retention mechanism 124 correspond to the spacing between the connectors 120 of FIG. 1. In one or more examples, different retention mechanism 124 can be designed for different connector layouts. The retention elements 210 may be on a single side of the memory module 122 as is illustrated in FIG. 3A. In the example of FIG. 3B, the retention elements 310 include multiple (e.g., two or more) extensions 311 that are on multiple sides of the memory module 122 (e.g., two or more). In one or more examples, each slot 230 may be associated with one retention element 210 or two or more retention elements 210.

As illustrated in FIG. 3C, the retention elements 210 are depressed along the direction 320 to lock (e.g., secure of fix) the memory modules 122 into place within a corresponding slot 230. Locking a memory module 122 within a corresponding slot mitigates movement of the memory modules 122. For example, as is illustrated in FIG. 3D, the retention elements 210 were depressed (engaged) and are secured against the surface 213 of the retention mechanism 124. In one example when depressed, the retention elements 210 do not contact the surface 213 of the retention mechanism 124.

In one or more examples, the spacing of the memory modules 122 is maintained based on the spacing of the connectors 120. The retention mechanism 124 and retention elements 210 mitigate motion (or movement) of the memory modules 122, reducing stress on the connectors 120 and physical and electrical failures. The retention mechanism 124 adds rigidity and reliability to connection between the memory modules 122 and the corresponding mating connector 120. In computer systems that do not include a retention mechanism 124, movement and vibrations of the computer systems may cause a memory module 122 to become dislodged from the connector 120, causing an electrical and/or mechanical failure. In one or more examples, to provide the increased rigidity, a memory module 122 is not installed in each slot of the retention mechanism 124.

In one example, the retention mechanism 124 may optionally include one or more heatsinks, function as a heatsink (or thermal reduction mechanism or heat transferring device) and/or contact the heatsinks 330 mounted to the memory modules 122. For example, one or more heatsinks 330 are mounted to a memory module 122. The heatsinks 330 may be external to the retention mechanism 124. In one example, the heatsinks 330 may be part of the retention mechanism 124. In one or more examples, the retention mechanism 124 is configured to hold, or at least partially hold, the heatsinks 330 to the memory module 122. In one or more examples, one or more heatsinks 330 is mounted to multiple memory modules 122. In yet other example, the heatsinks 330 are supported by the chassis of the computing system 100, for example using standoffs, such that the memory modules 122 may be installed between (i.e., interleaving with) adjacent the heatsinks 330 extending from the chassis.

In one or more examples, the retention mechanism 124 is configured to function as a heatsink. For example, the retention mechanism 124 may be formed from a metal material or multiple metal materials. In one example, the retention mechanism 124 is formed from aluminum, copper, or an alloy, among others. In other examples, other types of materials may be used. The retention mechanism 124 makes contact with the heatsinks 330, and provides a thermal pathway for heat to be transferred from the memory modules 122 to the heatsinks 330, and from the heatsinks 330 to the retention mechanism 124, further aiding in transferring heat away from the memory modules 122.

As is illustrated in example of FIG. 3E, the retention mechanism 124 may include one or more heat transferring elements 340. The heat transferring elements 340 may be a thermal exchange systems. In one example, the heat transferring elements 340 includes fins or other types of extensions that function to transfer heat away from the memory modules 122. The heat transferring elements 340 may include active or passive cooling. In one or more examples, the heat transferring elements 340 includes one or more phase change cavities, heat pipes, thermoelectric devices, and/or channels for forced flow liquid cooling. The phase change cavities may be include a phase changer material selected to provide cooling at operational temperatures.

In one example, the retention elements 210 function as a heat transferring element (e.g., a heatsink or other device). For example, the retention elements 210 may be extended to contact a larger surface area of the memory module 122. The retention elements 210 may be formed from aluminum, copper, or an alloy, among others.

FIG. 3F illustrates an alternative example of a retention mechanism, the retention mechanism 364. As is illustrated in FIG. 3F the retention mechanism 364 includes retention elements 360. The retention mechanism 364 is configured similar to the retention mechanism 124 and the retention elements 360 are configured to the retention elements 210. As compared to the retention elements 210, the retention elements 360 extend through the body of the retention mechanism 364. The memory modules 122 are inserted into the retention mechanism 364 along the direction 370. During installation, the memory modules 122 contact the retention elements 360, and push the retention elements 360 through the body of the retention mechanism 364 until the memory modules 122 contact the retention mechanism 364. The retention elements 360 hold the memory modules 122 in place similar to as is described above with regard to the retention elements 210.

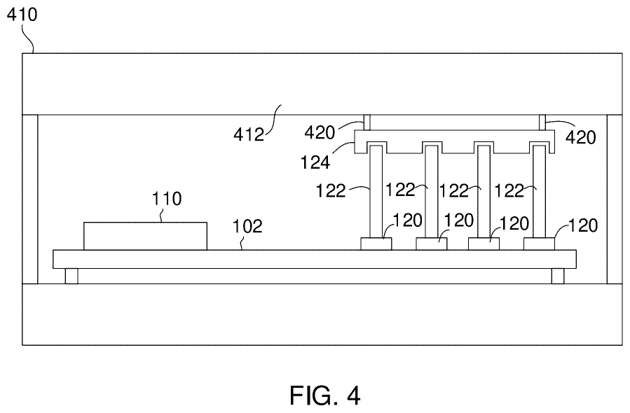

As is illustrated in FIG. 4, the retention mechanism 124 is mounted to the chassis 410 of the computer system 100. For example, the retention mechanism 124 may be mounted to a removable side or lid, or a non-removable side of the housing. In one example, the retention mechanism 124 is included within the frame of the chassis 410. The retention mechanism 124 is mounted to the chassis along a side that is opposite the side to which the PCB 102 is mounted or a side the perpendicular to the side to which the PCB 102 is mounted. In one example, the retention mechanism 124 is mounted to a lid 412 of the chassis 410. The retention mechanism 124 is mounted to the chassis via standoffs 420. The standoffs 420 are mounted to the lid 412 or the chassis 410 and connected to the retention mechanism 124. In one example, the standoffs 420 are omitted, and the retention mechanism 124 is mounted directly to the chassis 410 or the lid 412. In other examples, the retention mechanism 124 is formed as part of the chassis 410. In other examples, the retention mechanism 124 is not connected to or part of the chassis 410. For example, the retention mechanism 124 may be a standalone element.

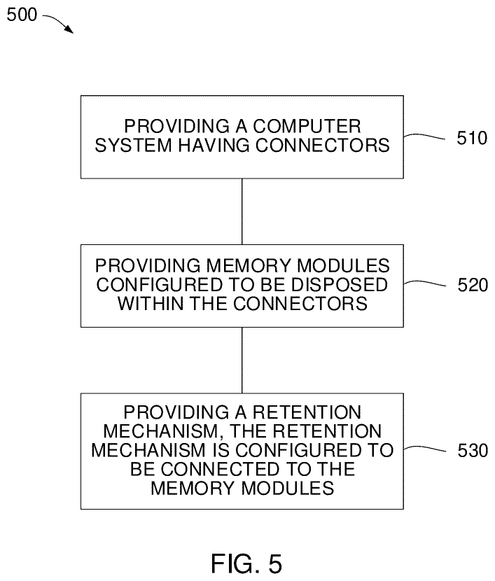

FIG. 5 illustrates a flowchart of a method 500 for providing a computer system (e.g., the computer system 100 of FIG. 1) having a retention mechanism (e.g., the retention mechanism 124 of FIG. 1) configured to secure the memory modules (e.g., the memory modules 122 of FIG. 1) within the computer system.

At block 510 of the method 500, a computer system having connectors is provided. For example, the computer system 100 of FIG. 1 is provided with the connectors 120. Each of the connector is configured to receive a memory module 122.

At block 520 of the method 500, memory modules that are configured to be disposed within the connectors are provided. For example, the memory modules 122 are provided. The memory modules 122 are installed (e.g., disposed) within the connectors 120. A respective memory module 122 is installed within a respective connector.

At block 530 of the method 500, a retention mechanism is provided that is configured to be connected to the memory modules. For example, the retention mechanism 124 is provided. The retention mechanism 124 includes slots 230. A memory module 122 is inserted within a respective slot 230. In one or more examples, to install the memory modules 122, the memory modules 122 are slid (e.g., inserted) into the slots 230. The slots 230 have a shape and/or include an alignment element such that the memory modules 122 are able to mate (e.g., slide) into the correct slot 230. In one example, the retention elements 210 are depressed to lock (e.g., secure of fix) the memory modules 122 into place, mitigating movement of the memory modules 122. In another example, with reference to FIG. 3F, the memory module 122 apply pressure to the retention mechanisms 364 when installed.

As is described in the above, the retention mechanism and retention elements mitigate movement of the memory modules, reducing stress on the connectors and physical and electrical failures. The retention mechanism adds rigidity and reliability to connection between the memory modules and the corresponding mating connector.

While the foregoing is directed to specific examples, other and further examples may be devised without departing from the basic scope thereof, and the scope thereof is determined by the claims that follow.

What is claimed is:

1. A computer system comprising:
connectors;
memory modules disposed within the connectors; and
a retention mechanism connected to the memory modules, the retention mechanism includes slots, each of the slots configured to receive one of the memory modules.

2. The computer system of claim 1, wherein the retention mechanism includes retention elements that align the memory modules within the slots.

3. The computer system of claim 2, wherein a first retention element of the retention elements is configured to contact a first memory module of the memory module to align the first memory module with a first slot of the slots.

4. The computer system of claim 3, wherein the first retention element is configured to contact a first side and a second side of the first memory module.

5. The computer system of claim 1, wherein the retention mechanism is formed from a plastic material or a metal material.

6. The computer system of claim 1, wherein the retention mechanism is configured to function as a heat transfer device for the memory modules.

7. The computer system of claim 1, wherein the retention mechanism is configured to contact a heatsink mounted to the memory modules.

8. The computer system of claim 1 further comprising a chassis, and wherein the retention mechanism is connected to the chassis or part of the chassis.

9. The computer system of claim 1, wherein a spacing of the slots corresponds to a spacing of the connectors.

10. A retention mechanism comprising:
slots, each slot of the slots configured to receive a memory module of memory modules of a computer system, wherein the memory modules are disposed within connectors of the computer system.

11. The retention mechanism of claim 10, wherein the retention mechanism includes retention elements that align the memory modules within the slots.

12. The retention mechanism of claim 11, wherein a first retention element of the retention elements is configured to contact a first memory module of the memory module to align the first memory module with a first slot of the slots.

13. The retention mechanism of claim 12, wherein the first retention element is configured to contact a first side and a second side of the first memory module.

14. The retention mechanism of claim 10, wherein the retention mechanism is formed from a plastic material or a metal material.

15. The retention mechanism of claim 10, wherein the retention mechanism is configured to function as a heat transfer device for the memory modules.

16. The retention mechanism of claim 10, wherein the retention mechanism is configured to contact a heatsink mounted to the memory modules.

17. A method comprising:
providing a computer system comprising connectors;
providing memory modules, wherein the memory modules are configured to be disposed within the connectors; and
providing a retention mechanism, wherein the retention mechanism is configured to be connected to the memory modules, the retention mechanism includes slots, each of the slots configured to receive one of the memory modules.

18. The method of claim 17, wherein the retention mechanism includes retention elements that align the memory modules within the slots, and wherein a first retention element of the retention elements is configured to contact a first memory module of the memory modules to align the first memory module with a first slot of the slots.

19. The method of claim 17, wherein at least one of the retention mechanism is configured to function as a heat transfer device for the memory modules, or the retention mechanism is configured to contact a heatsink mounted to the memory modules.

20. The method of claim 17, wherein the retention mechanism is connected to a chassis of the computer system or part of the chassis.
